(19) United States
(12) Patent Application Publication
(10) Pub. No.: US 2020/0184919 A1
(43) Pub. Date: Jun. 11, 2020

(54) SENSOR MEASURING SYSTEM AND METHOD FOR ASSIGNING A SENSOR IN A SENSOR MEASURING SYSTEM

(71) Applicant: Endress+Hauser Conducta GmbH+Co. KG, Gerlingen (DE)

(72) Inventor: Benoit Labrique, Stuttgart (DE)

(21) Appl. No.: 16/705,521

(22) Filed: Dec. 6, 2019

(30) Foreign Application Priority Data
Dec. 7, 2018 (DE) 10 2018 131 435.3

(51) Int. Cl. G09G 5/00; G01R 1/04; H01R 13/66

(52) U.S. Cl. CPC G09G 5/003; H01Q 1/2291; H01R 13/6683; G01R 1/0416

(57) ABSTRACT

The present disclosure relates to an automation sensor measuring system comprising a plurality of sensors, wherein for at least one of the sensors a display signal at a connection element display unit can be adapted and/or is adapted to a display signal relating to the respective sensors at the superordinate display/input unit, whereby the respective sensor can be assigned to a display at the superordinate display/input unit. The present disclosure further relates to a method for assigning a sensor in an automation sensor measuring system.

### CROSS-REFERENCE TO RELATED APPLICATION

The present application is related to and claims the priority benefit of German Patent Application No. 10 2018 131 435.3, filed on Dec. 7, 2018, the entire contents of which are incorporated herein by reference.

### TECHNICAL FIELD

The present disclosure relates to an automation sensor measuring system, comprising a plurality of sensors which are respectively designed to generate at least one measurement signal dependent on a process variable of a medium, and a respective sensor connection element which is assigned to the sensor and is designed for transmitting power to the respective sensor and for transmitting and/or receiving data to/from the respective sensor.

### BACKGROUND

For processing and/or forwarding of the electronic and/or electrical signals generated by a sensor, for example to a transmitter unit or a superordinate control unit (for example to a control station), the sensor is often connected to a sensor connection element. A sensor connection element of this type is described in DE 10 2009 055 247 A1, for example. The sensor connection element comprises a cable attachment and a cable, which in turn is connected to the superordinate control unit.

An interface that, for example, is designed to be inductive or optical is respectively located at the sensor and at the sensor connection element. These supply the sensor with power and/or ensure communication between sensor and sensor connection element; this is described in EP 1 625 643, for example. Reference should also be made here especially to the products with the name “Memosens” from the applicant. Other generic embodiments are, for instance, “Memosens” by the company Knick, “ISM” by Mettler-Toledo, the “ARC” system by Hamilton, and “SMARTSENS” by Krohne. The great advantage of the known “Memosens” plug connection is its liquid-tight design and the very simple removal of the sensor from a process.

The “Memosens” plug connection is especially advantageous in conjunction with electrochemical sensors. Electrochemical sensors are used for the analysis of measurement media in laboratory and process metrology in many fields of chemistry, biochemistry, pharmacy, biotechnology, food technology, water management, and environmental metrology. Electrochemical sensors can, for example, be potentiometric (for example ion-selective electrodes (ISE), for instance the known pH glass electrode) or amperometric sensors (for example amperometric disinfection sensors). Further examples of electrochemical sensors are those based on electrolyte-insulator-semiconductor layer stacks (EIS for short), inductively or capacitively operating conductivity sensors, or sensors operating (spectro)photometrically, such as turbidity sensors.

In the instance of a sensor measuring system with, for example, a plurality of sensors, such a sensor connection element that is respectively connected to the superordinate control unit with a separate cable is provided for each of the sensors. Measured values and/or instructions, for example in the context of a calibration of a respective sensor, are often displayed on a superordinate display/input unit of the superordinate control unit, for example. In the event of a plurality of sensors, assigning a display pertaining to a respective sensor to the superordinate display/input unit for the respective sensor is difficult. This assignment is especially difficult if a plurality of sensors of the same species is used, for example a plurality of pH sensors.

### SUMMARY

The object of the present disclosure is therefore to be able to assign a display at a superordinate display/input unit as simply as possible to a respective sensor in an automation sensor measuring system.

The object is achieved by a sensor measuring system and a method for assigning a sensor in a sensor measuring system.

With regard to the sensor measuring system, the object is achieved by an automation sensor measuring system, comprising:
a plurality of, especially at least two, sensors which are respectively designed to generate at least one measurement signal dependent on a process variable of a medium, as well as a respective sensor connection element which is assigned to the respective sensor and is designed for transmitting power to the respective sensor and for transmitting and/or receiving data to/from the respective sensor, wherein the sensor connection elements respectively have a connection element display unit, and
a superordinate control unit which is connected to each of the sensor connection elements via a communication connection belonging to the respective sensor connection element, which communication connection is designed to transmit the data between the sensor connection element and the superordinate control unit,

wherein the superordinate control unit is designed to control and/or regulate the sensors and/or to evaluate and/or further process the data transmitted by the sensors, and has a superordinate display/input unit,

and wherein, for at least one of the sensors, a display signal at the connection element display unit can be adapted and/or is adapted to a display signal relating to the respective sensor at the superordinate display/input unit, whereby the respective sensor can be assigned to a display on the superordinate display/input unit.

The advantages of the present disclosure are as follows:
By adapting the display signals, the respective sensor can advantageously be directly assigned to the display on the superordinate display/input unit. This saves time, for example for a user, in implementing instructions displayed on the superordinate display/input unit.
Furthermore, the operator safety is increased by adapting the display signals. This is of particular importance in the aforementioned industries, for example the pharmaceutical and food industry. High safety standards are the norm here, and operating errors must absolutely be avoided.
Furthermore, the adapted display signals make it easier for a user to execute calibration and measurement tasks indicated on the superordinate display/input unit simultaneously, for example for different sensors. This parallelization in turn saves time or increases productivity.

The superordinate display/input unit is a unit designed for display and/or input. The plurality of sensors is especially at least two sensors, but a multitude of sensors is also conceivable.

In one embodiment of the present disclosure, the display signals are optical display signals, wherein the display signal at the connection element display unit is adapted in color to the display signal at the superordinate display/input unit.

In one embodiment of the sensor measuring system, the connection element display unit of the sensor connection element of the at least one sensor comprises an LED and/or a display.

In one embodiment, the display is realized as an LCD, OLED display, or electronic paper display (e-ink).

In one embodiment of the sensor measuring system, the communication connection to the superordinate control unit is wired for at least one of the sensor connection elements, and/or the communication connection to the superordinate control unit is wireless for at least one of the sensor connection elements.

In the event that the communication connection is designed as a wired communication connection, it can be, for example, a wired automation field bus, for example Foundation Fieldbus, Profibus PA, Profibus DP, HART, CANBus etc. However, it can also be a modern industrial communication connection, for example an “Industrial Ethernet” field bus, especially Profinet, HART-IP, or Ethernet/IP, or a communication connection known from the field of communication, for example Ethernet according to the TCP/IP protocol. Thus, the communication connection can especially also be part of a communication network.

In the event that the communication connection is configured as a wireless communication connection, it can be, for example, a Bluetooth, ZigBee, WLAN, GSM, LTE, UMTS communication connection, or else also a wireless version of a field bus, especially 802.15.4-based standards such as WirelessHART. In this instance as well, the communication connection can especially be part of a communication network.

In a further embodiment of the sensor measuring system, the sensor connection element comprises:
a first inductive interface designed to transmit power to the sensor and transmit/receive data to/from the sensor, and
a first data processing unit.

In a further embodiment of the sensor measuring system, the sensor respectively comprises:
a second inductive interface which is designed to be complementary to the first inductive interface of the respective sensor connection element,
at least one sensor element which is designed to detect the process variable, and
a second data processing unit which, via the second inductive interface of the sensor, transmits data dependent on the process variable and representative of the measurement signal to the first inductive interface of the sensor connection element, and receives data thereby.

In this context, reference is again made to the “Memosens” plug connection mentioned above.

In a preferred development of the sensor measuring system, for at least one of the sensors, the associated sensor connection element is designed to be self-sufficient in terms of energy, and the energy-self-sufficient sensor connection element comprises:
an energy store,
at least one wireless module which can be controlled by the first data processing unit to generate the wireless communication connection.

The energy store is a rechargeable battery, for example. This can especially be wirelessly rechargeable, for example by means of the “Qi” charging technology. In conjunction with this development, the present disclosure is especially advantageous since, in this instance of an energy-self-sufficient sensor connection element, a cable used for supplying power no longer needs to be routed to the sensor connection element.

In the event of a wireless communication connection, the superordinate control unit then is or can be connected only wirelessly to the sensor connection element, for example by means of the aforementioned wireless communication network or the wireless communication connection. In the event of such a wireless communication connection, a color-adapted display for assigning the sensor to the display at the superordinate display/input unit is especially helpful.

In one embodiment of this development of the sensor measuring system, a first wireless module of the sensor connection element is designed as a Bluetooth, WLAN, and/or infrared module, and/or a second wireless module of the sensor connection element is designed as a mobile radio module, wherein the wireless communication connection can be established by means of the first wireless module and/or the second wireless module.

The mobile radio module is, for example, designed according to one of the mobile radio standards GPRS, EDGE, UMTS, HSDPA, LTE, or 5G.

In a further development of the sensor measuring system, the superordinate control unit can be or is integrated at least partially into a mobile terminal, especially its superordinate display/input unit.

The mobile terminal can be a smartphone, a laptop and/or tablet, smartglasses, or a mobile terminal specific to process automation, such as the FieldXpert distributed by Endress+Hauser.

In one embodiment of the sensor measuring system, at least one of the sensors is designed as an electrochemical sensor, especially as a pH, redox, conductivity, or dissolved oxygen sensor. Of course, one of the sensors can also be designed as another of the aforementioned electrochemical sensors.

With regard to the method for assigning a sensor in an automation sensor measuring system, the object is achieved by a method for assigning a sensor in an automation sensor measuring system, wherein the sensor measuring system comprises:
a plurality of sensors, especially at least two, which are respectively designed to generate at least one measurement signal dependent on a process variable of a medium, and a respective sensor connection element which is assigned to the sensor and is designed for transmitting power to the respective sensor and for transmitting and/or receiving data to/from the respective sensor, wherein the sensor connection elements respectively have a connection element display unit, and
a superordinate control unit which is connected to each of the sensor connection elements via a communication connection belonging to the respective sensor connection element, which communication connection is designed to transmit the data between the sensor connection element and the superordinate control unit,

wherein the superordinate control unit is designed to control and/or regulate the sensors, and/or to evaluate and/or further process the data transmitted by the sensors, and has a superordinate display/input unit,

and wherein, for at least one of the sensors, the method comprises the following step:
adapting a display signal at the connection element display unit to a display signal relating to the respective sensor at the superordinate display/input unit, whereby the respective sensor is assigned to a display at the superordinate display/input unit.

In one embodiment of the method, these are optical display signals, wherein the display signal at the connection element display unit is matched in color to the display signal at the superordinate display/input unit.

In one embodiment of the method, this comprises the following steps:
executing a computer program product that is executable in the superordinate control unit, wherein a guided menu is displayed at the superordinate display/input unit upon execution of the computer program product;
in the guided menu, assigning a sensor to a display pertaining to the sensor by means of adapting the display signal at the connection element display unit to the display signal displayed in the guided menu.

Such a computer program product is, for example, part of the system distributed by the applicant under the name “Memobase Plus.”

In one embodiment of the method, the appertaining sensor is in a measurement mode in which a process variable is determined by the superordinate control unit from the measurement signal of a respective sensor, and the method comprises the steps:
display the process variable at the superordinate display/input unit
display the process variable at the connection element display unit.

In one embodiment of the method, the appertaining sensor is in a calibration mode in which an instruction is determined and/or output by the superordinate control unit within the scope of a calibration of a respective sensor, and the method comprises the steps:
display the instruction at the superordinate display/input unit
display the instruction at the connection element display unit.

### BRIEF DESCRIPTION OF THE DRAWINGS

The present disclosure will be explained further with reference to Figures which are not true to scale, wherein the same reference characters designate the same features. For reasons of clarity, or if it appears sensible for other reasons, reference characters that have already been noted are omitted in subsequent Figures. These show:

FIG. 1A, 1B: a first embodiment of the measuring system according to the present disclosure;

FIG. 2: a second embodiment of the measuring system according to the present disclosure; and

FIG. 3A, 3B: a further embodiment of the method according to the present disclosure.

### DETAILED DESCRIPTION

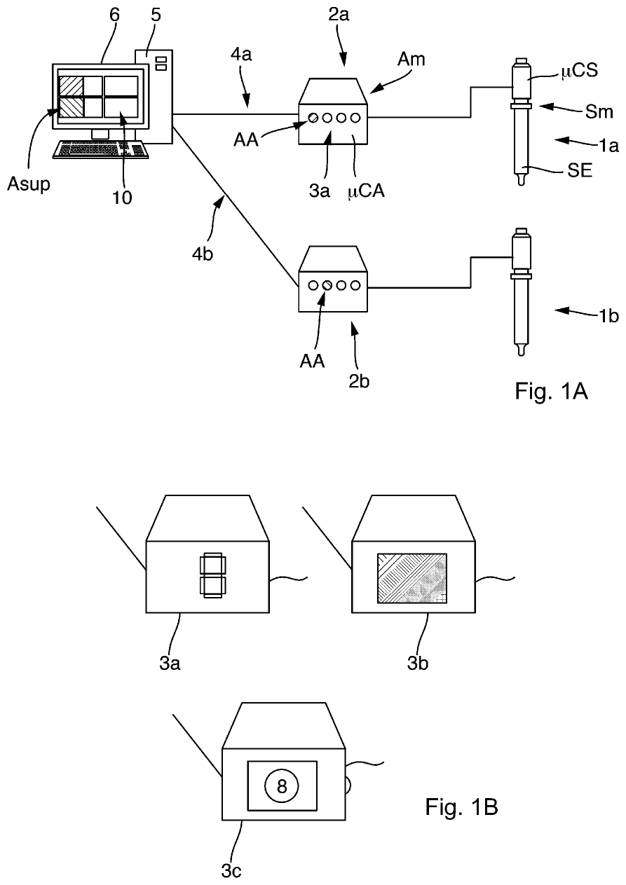

FIG. 1 shows a first embodiment of the measuring system according to the present disclosure, comprising two electrochemical sensors 1a, 1b, in this instance two pH probes. The two sensors 1a, 1b respectively have a sensor element SE which serves to detect a measurement signal (explained here and hereinafter only on the first sensor 1a). The measurement signal depends on the pH value of a process medium with which the sensor element SE is in contact in a measuring operation. Furthermore, the sensors 1a, 1b comprise a second inductive interface Sm via which the electrical power required for detecting the measurement signal can be transmitted to the sensor element SE. Data can be transmitted (see aforementioned Memosens interface) in both directions between the sensor element SE and a second data processing unit μCS, for example a microcontroller of the sensor 1a; 1b. The signal generated by the sensor 1a; 1b (for example in a Memosens protocol) is then forwarded to a respective sensor connection element 2a; 2b.

The sensor connection element 2a; 2b has a first data processing unit μCA and a first inductive interface Am. The data which the data processing unit μCA processes are, for example, measured values and calculations thereof, for instance averages, smoothing etc., or conversions into another data format or adaptations to a specific communication system, such as a specific field bus.

The sensor connection element 2a; 2b further comprises a connection element display unit 3a; 3b. The connection element display unit 3a; 3b in this instance is one or more LEDs, preferably multi-colored.

The sensor connection element 2a; 2b is respectively connected to a superordinate control unit 5 with a cable, whereby a wired communication connection 4a, 4b with the superordinate control unit 5 exists. In this instance, the superordinate control unit 5 is a computer and the communication connection 4a, 4b is respectively a USB cable.

In the event that the sensor connection element 2a; 2b is not self-sufficient in terms of energy, power is supplied to the sensor connection element 2a; 2b by means of said communication connection 4a, 4b or via a further cable, so that the power supply of the sensor connection element 2a; 2b or of the sensor 1a; 1b is always ensured. For this purpose, the sensor connection element 2a; 2b can be connected to a wired power source, for example a USB charger, so that a continuous supply of power to the sensor connection element 2a; 2b via the power network results.

A guided menu 10 of a computer program product, in which measured values and/or steps of a calibration or instruction are displayed within the context of a measurement mode or calibration mode, is displayed at a superordinate display/input unit 6, in this instance a screen with a keyboard connected to the computer. This solution is distributed by the applicant under the name, “Memobase Plus.”

According to the present disclosure, a display signal AA that is displayed by means of the LEDs of the connection element 3a; 3b is adapted to a display signal Asup displayed at the superordinate display/input unit 6. In the event of multicolor LEDs, a first LED can be interpreted as a channel assignment, in such a way that to which sensor 1a, 1b the display signal Asup displayed at the superordinate display/input unit 6 relates can be perceived directly at the connection element 2a, 2b.

A second LED can, for example, be reserved for a measurement view in which a sensor 1a; 1b that is used for a plurality of samples and/or a plurality of process variables can be assigned to a respective sample measurement. For example, for a specific sample the pH value and the conductivity value are determined simultaneously with two sensors 1a, 1b.

In addition to this channel assignment that is thus enabled, the LEDs can also be used to display a needed action, for example in the context of a calibration (“Now immerse the first sensor la in buffer 7.00 pH”) according to a specification on the screen. This is achieved by a specific LED flashing, for example.

Alternatively or additionally, the connection element display unit 3c (see FIG. 1B), for example a further sensor 1c, can be designed as a segment display, a display, or a rotary wheel with a digit or color sequence.

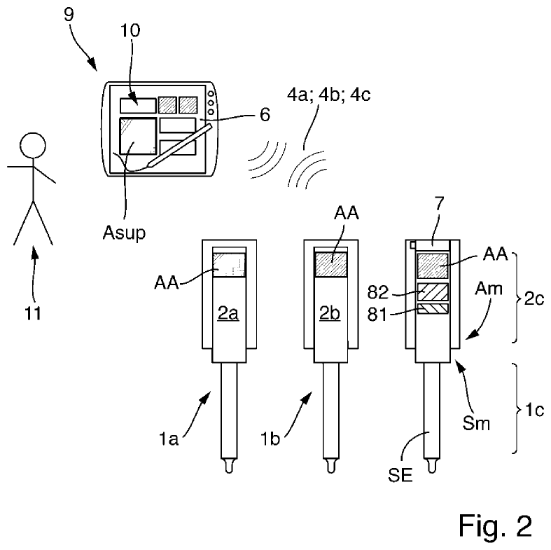

A further embodiment of the measuring system with three sensors 1a, 1b, 1c is shown in FIG. 2. The sensor connection element 2c (explained here and hereinafter only in the example of the third sensor 1c, for the sake of simplicity) here comprises an energy store 7 and two wireless modules 81, 82. The connection element display unit 3c is in this instance a display, wherein all the variants of the connection element display unit 3c (LEDs, segment display, rotary wheel with a digit or color sequence) that have already been shown in conjunction with FIGS. 1A, 1B are of course also possible, and are not explicitly shown here again.

In this instance, the sensor connection element 2c is respectively arranged close to the sensor and is connected to the sensor 1c by means of two mutually compatible interfaces Am, Sm. Power is transmitted to the sensor 1c by means of the energy store 7. The sensor connection element 2c can thus be regarded as energy-independent. The energy store 15 is designed as a preferably chargeable battery, for example a lithium ion accumulator. The energy store 15 is preferably charged wirelessly, for example by means of the “Qi” charging technology. Alternatively or additionally, energy store 15 can be charged by means of a solar cell.

The sensor connection element 2c comprises wireless modules 81, 82 for the transmission and reception of data at the superordinate control unit 5 by radio connection. This takes place here with a mobile terminal 9 which can be connected to a communication network, for example WLAN, by means of which a communication connection 4c can be established between the sensor connection element 2c and the superordinate control unit 5. The mobile terminal 9 is a smartphone or tablet, for instance, but can also be designed as a computer, and comprises the superordinate display/input unit 6. The “data” may be measurement data of the sensor 1c. However, the data may also be configuration values (parameters) of the sensor 1c. The sensor 1c is thereby parameterized via the mobile terminal 9, and the parameterization is transmitted by means of the interfaces Am, Sm to the sensor connection element 2c and then to the sensor 1c.

The mobile terminal 9 has a corresponding interface or transmitting/receiving module. Data transmitted and received by the first or second wireless module 81, 82 are, for instance, the already addressed measured values, calculations thereof, or conversions thereof. Furthermore, firmware updates, changes to settings of the sensor 1a, 1b or of the sensor connection element 2c, or meta-information, such as location information or the measurement site name etc. are also transmitted via the wireless module 81, 82.

Of course, a measuring system using a combination of the embodiments shown in FIG. 1A and FIG. 2 is also possible. For example, the measuring system may use a first one of the sensor connection elements 2a; 2b; 2c as shown in FIG. 1A, and may further use a second one of the sensor connection elements 2a; 2b; 2c as shown in FIG. 2.

As already shown in FIG. 1B, the connection element display unit 3a, 3b, 3b is a multicolor display (OLED, . . . ) at which the sample measurement assignments and/or measurement channel assignments can be represented by means of color and/or text.

Thus, it is immediately recognizable to a user 11 to which sensor 1a, 1b, 1c a measurement displayed at the display/input unit 6 of the mobile terminal 9 belongs, even if the sensors 1a, 1b, 1c are all of the same species. In addition, it can be immediately discerned at the sensor 1a, 1b, 1c whether there is any need to take action, e.g. in which sample or calibration buffer the sensors 1a, 1b, 1c are to be immersed at a point in time specified by a computer program product, or whether a cleaning step is required (“action required”).

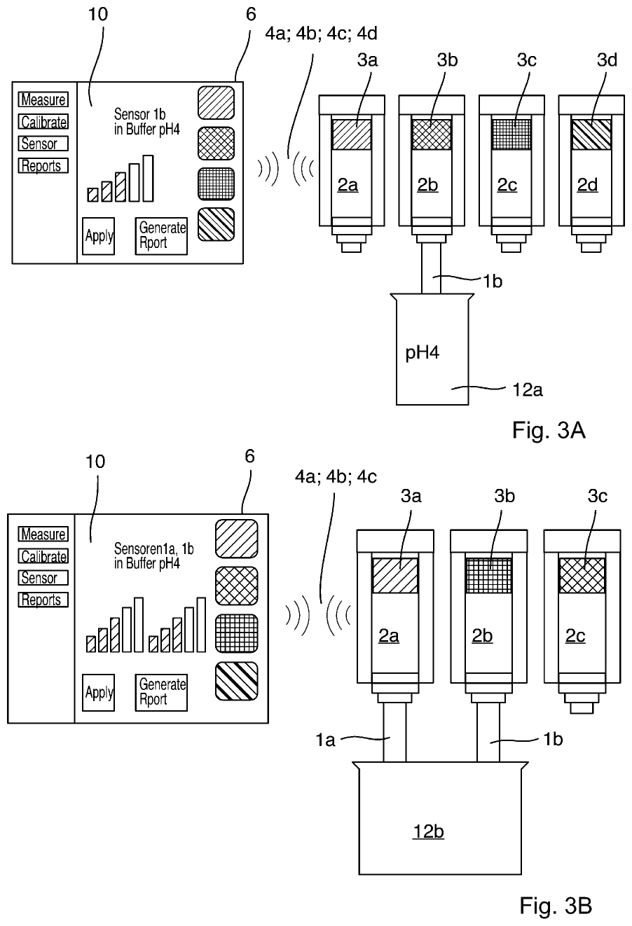

This is shown in FIG. 3A, 3B. A respective color is associated with each of the sensor connection elements 2a, 2b, 2c, 2d, wherein FIG. 3A shows a calibration mode and FIG. 3B shows a measurement mode. The color on the display 3a, 3b, 3c, 3d of the sensor connection elements 2a, 2b, 2c, 2d is matched to the color of a display signal Asup which is displayed at the superordinate display unit 6, and relates to a respective sensor 1a; 1b; 1c; 1d.

The user 11 thereby immediately knows on which of the sensors 1a; 1b; 1c; 1d he must concentrate, for example within the context of a calibration, FIG. 3A. Because multiple sensors 1a, 1b, 1c 1d can be calibrated simultaneously, it is thereby clear to which of the sensors 1a, 1b, 1c, 1d an instruction relates, for example “Immerse sensor 2b in a container 12a with buffer pH 4.”

FIG. 3B shows how a specific color is additionally used in a measurement mode for a specific sample, for example in a fermenter 12b. In the measuring mode, this is selected at the same time as the color on the display 3a, 3b of the sensor connection elements 2a, 2b, and as the color of a display signal Asup at the superordinate display/input unit 6. For example, each fermenter is assigned a specific color.

In addition or as an alternative to the matching of the color, text can also be displayed at the display 3a, 3b, 3c, 3d which is matched to the text in the guided menu 10 of the computer program product.

1. An automation sensor measuring system, comprising:
at least two sensors which are respectively designed to generate at least one measurement signal dependent on a process variable of a medium, and a respective sensor connection element which is assigned to the respective sensor and is designed for transmitting power to the respective sensor and for transmitting and/or receiving data to/from the respective sensor, wherein the sensor connection elements respectively have a connection element display unit; and
a superordinate control unit which is connected to each of the sensor connection elements via a communication connection belonging to the respective sensor connection element, which communication connection is designed to transmit the data between the sensor connection element and the superordinate control unit,
wherein the superordinate control unit is designed to control and/or regulate the sensors and/or to evaluate and/or further process the data transmitted by the sensors, and has a superordinate display/input unit, and
wherein, for at least one of the sensors, a display signal at the connection element display unit is adaptable and/or adapted to a display signal at the superordinate display/input unit that relates to the respective sensor, whereby the respective sensor can be assigned to a display at the superordinate display/input unit.

2. The sensor measuring system according to claim 1,
wherein the display signals are optical display signals, and
wherein the display signal at the connection element display unit is adapted in terms of color to the display signal at the superordinate display/input unit.

3. The sensor measuring system according to claim 1,
wherein the connection element display unit of the sensor connection element of at least one sensor comprises an LED and/or a display.

4. The sensor measuring system according to claim 1,
wherein the communication connection is wired to the superordinate control unit for at least one of the sensor connection elements, and/or
wherein the communication connection with the superordinate control unit is wireless for at least one of the sensor connection elements.

5. The sensor measuring system according to claim 1,
wherein the sensor connection element respectively includes:
a first inductive interface designed for transmitting power to the sensor and for transmitting/receiving data to/from the sensor, and
a first data processing unit.

6. The sensor measuring system according to claim 5, wherein the respective sensor includes:
a second inductive interface which is designed to be complementary to the first inductive interface of the respective sensor connection element,
at least one sensor element which is designed to detect the process variable, and
a second data processing unit which transmits data dependent on the process variable and representing the measurement signal via the second inductive interface of the sensor to the first inductive interface of the sensor connection element, and receives data from the first inductive interface of the sensor connection element.

7. The sensor measuring system according to claim 1,
wherein, for at least one of the sensors, the associated sensor connection element is designed to be self-sufficient in terms of energy, and the energy-self-sufficient sensor connection element includes:
an energy store, and
at least one wireless module which can be controlled by the first data processing unit to generate the wireless communication connection.

8. The sensor measuring system according to claim 7,
wherein a first wireless module of the sensor connection element is designed as a Bluetooth, WLAN, and/or infrared module, and/or
wherein a second wireless module of the sensor connection element is designed as a mobile radio module, and
wherein the wireless communication connection can be established by means of the first wireless module and/or the second wireless module.

9. The sensor measuring system according to claim 1,
wherein the superordinate control unit can be integrated or is integrated at least partially into a mobile terminal, including the superordinate display/input unit.

10. The sensor measuring system according to claim 1,
wherein at least one of the sensors is designed as an electrochemical sensor, a pH sensor, a redox sensor, a conductivity sensor, or a dissolved oxygen sensor.

11. A method for assigning a sensor in an automation sensor measuring system, comprising:
providing a sensor measuring system, including:
at least two sensors, which are respectively designed to generate at least one measurement signal dependent on a process variable of a medium, and a respective sensor connection element which is assigned to the respective sensor and is designed for transmitting power to the respective sensor and/or transmitting and/or receiving data to/from the respective sensor, wherein the sensor connection elements respectively have a connection element display unit; and
a superordinate control unit which is connected to the respective sensor connection elements via a communication connection belonging to the respective sensor connection element, which communication connection is designed to transmit the data between the sensor connection element and the superordinate control unit;
wherein the superordinate control unit is designed to control and/or regulate the sensors, and/or to evaluate and/or further process the data transmitted by the sensors, and has a superordinate display/input unit; and
adapting a display signal at the connection element display unit to a display signal relating to the respective sensor at the superordinate display/input unit, whereby the respective sensor is assigned to a display on the superordinate display/input unit.

12. The method according to claim 11,
wherein the display signals are optical display signals, and wherein the display signal at the connection element display unit is matched in terms of color to the display signal at the superordinate display/input unit.

13. The method according to claim 11, further comprising the steps:
executing a computer program product executable in the superordinate control unit, wherein a guided menu is displayed on the superordinate display/input unit when the computer program product is executed; and
assigning a sensor to a display in the guided menu, said display pertaining to the sensor, by means of the adaptation of the display signal at the connection element display unit to the display signal displayed in the guided menu.

14. The method according to claim 13,
wherein the relevant sensor is in a measuring mode, in which a process variable is determined by the superordinate control unit from the measurement signal of a respective sensor, comprising the steps of:
displaying the process variable at the superordinate display/input unit; and
displaying the process variable at the connection element display unit.

15. The method according to claim 13,
wherein the relevant sensor is in a calibration mode in which an instruction is determined and/or output by the superordinate control unit in the context of a calibration of a respective sensor, comprising the steps of:
displaying the instruction at the superordinate display/input unit; and
displaying the instruction at the connection element display unit.
